(19) United States
(12) Patent Application Publication
(10) Pub. No.: US 2025/0105044 A1
(43) Pub. Date: Mar. 27, 2025

(54) ELECTROSTATIC CHUCK, PLASMA PROCESSING METHOD, AND PLASMA PROCESSING APPARATUS

(71) Applicant: SEMES CO., LTD., Cheonan-si (KR)

(72) Inventors: Yong Jun BAE, Cheonan-si (KR); ASATUR KHURSHUDYAN, Cheonan-si (KR); Jun Seok PARK, Cheonan-si (KR); SHANT ARAKEL YAN, Cheonan-si (KR); Ja Myung GU, Cheonan-si (KR)

(73) Assignee: SEMES CO., LTD., Cheonan-si (KR)

(21) Appl. No.: 18/650,955

(22) Filed: Apr. 30, 2024

(30) Foreign Application Priority Data
Sep. 22, 2023 (KR) 10-2023-0126967

(51) Int. Cl. H01L 21/683; H01J 37/32

(52) U.S. Cl. CPC H01L 21/6833; H01J 37/3244; H01J 37/32724; H01J 2237/3341

(57) ABSTRACT

Proposed are an electrostatic chuck, a plasma processing method, and a plasma processing apparatus for preventing abrupt temperature changes in a substrate and maintain a constant temperature. The electrostatic chuck that supports a substrate in the plasma processing apparatus includes a puck on which a substrate for plasma processing is seated and having a heater, and a base plate located below the puck and having a cooling passage through which fluid for cooling flows. A temperature maintenance layer composed of a phase change material is provided inside the base plate.

### CROSS REFERENCE TO RELATED APPLICATION

The present application claims priority to Korean Patent Application No. 10-2023-0126967, filed on Sep. 22, 2023, the entire contents of which is incorporated by reference herein for all purposes.

### BACKGROUND

### Field of the Invention

The present disclosure relates to an electrostatic chuck supporting a substrate, a plasma processing method for a substrate supported by the electrostatic chuck, and a plasma processing apparatus including the electrostatic chuck.

### Description of the Related Art

Semiconductor manufacturing is a process of manufacturing semiconductor devices on a substrate (e.g., wafer), and includes, for example, exposure, deposition, etching, ion implantation, cleaning, etc. In order to perform each manufacturing process, semiconductor manufacturing equipment for performing individual processes is provided in cleanrooms of a semiconductor manufacturing plant so that a process is performed on a substrate put into the semiconductor manufacturing equipment.

In the semiconductor manufacturing, processes using plasma, such as etching and deposition, are widely used. A plasma processing process is performed by placing a substrate in the lower part of a plasma processing space and applying voltage by electrodes located at the top and bottom of the processing space along with the supply of fluid for plasma processing.

Meanwhile, during plasma processing, in order to control the temperature of a substrate, a process of supplying coolant through a cooling passage formed inside an electrostatic chuck that supports the substrate or operating a heater, which is also provided inside the electrostatic chuck, is performed. In the process of processing a substrate, it is necessary to keep the temperature constant at low temperature (e.g., −30° C.) or high temperature (e.g., 120° C.). However, since maintaining a constant temperature depends on the performance of a chiller that supplies coolant and the performance of a heater that heats a substrate, abrupt temperature changes may occur due to performance deviations, which is problematic.

### SUMMARY

Accordingly, the present disclosure has been made keeping in mind the above problems occurring in the related art, and an objective of the present disclosure is to provide an electrostatic chuck, a plasma processing method, and a plasma processing apparatus for preventing abrupt temperature changes in a substrate and maintain a constant temperature.

In order to accomplish the above objectives, according to an embodiment of the present disclosure, there is provided an electrostatic chuck that supports a substrate in a plasma processing apparatus. The electrostatic chuck includes: a puck on which a substrate for plasma processing is seated and having a heater; a base plate located below the puck and having a cooling passage through which fluid for cooling flows. A temperature maintenance layer composed of a phase change material may be provided inside the base plate.

According to an embodiment of the present disclosure, the temperature maintenance layer may have a disk shape corresponding to the substrate.

According to an embodiment of the present disclosure, the temperature maintenance layer may have a ring shape corresponding to an edge area of the substrate.

According to an embodiment of the present disclosure, the phase change material of the temperature maintenance layer may be determined based on a processing temperature of the substrate.

According to an embodiment of the present disclosure, the temperature maintenance layer may include: a first temperature maintenance layer composed of a first phase change material; and a second temperature maintenance layer stacked in a vertical direction on the first temperature maintenance layer and composed of a second phase change material different from the first phase change material.

According to an embodiment of the present disclosure, the first temperature maintenance layer and the second temperature maintenance layer may be stacked in contact with each other.

According to an embodiment of the present disclosure, the first temperature maintenance layer and the second temperature maintenance layer may be stacked while being spaced apart from each other.

According to an embodiment of the present disclosure, the temperature maintenance layer may be inserted into an internal space of the base plate.

According to an embodiment of the present disclosure, the temperature maintenance layer may be composed of a tube inserted into a circular conduit provided in the base plate.

According to an embodiment of the present disclosure, the temperature maintenance layer may be coupled to a groove formed on an upper surface of the base plate.

According to an embodiment of the present disclosure, a coating layer made of alumina (Al2O3) may be formed on an outer surface of the base plate.

According to an embodiment of the present disclosure, an adhesive layer may be formed between the puck and the base plate to adhere the puck and the base plate.

According to an embodiment of the present disclosure, a ring-shaped sealing member surrounding an outside of the adhesive layer may be provided between the puck and the base plate.

A plasma processing method according to the present disclosure includes: positioning a substrate on an electrostatic chuck including a puck with a heater and a base plate located below the puck and having a cooling passage formed therein; controlling a temperature of the substrate by adjusting an output of the heater and supplying coolant to the cooling passage; and performing processing on the substrate using plasma. A temperature maintenance layer composed of a phase change material may be provided inside the base plate.

A plasma processing apparatus according to the present disclosure includes: a chamber configured to form a plasma processing space for a substrate; an electrostatic chuck configured to support the substrate; an upper electrode configured to generate plasma in the plasma processing space; a window configured to separate the upper electrode from the plasma processing space; a power source configured to supply power to the upper electrode; a gas supply member configured to supply a processing gas to the plasma processing space; and a gas supply source configured to supply the processing gas to the gas supply member. The electrostatic chuck may include: a puck on which a substrate for plasma processing is seated and having a heater; and a base plate located below the puck and having a cooling passage through which fluid for cooling flows. A temperature maintenance layer composed of a phase change material may be provided inside the base plate, wherein the temperature maintenance layer may have a disk shape corresponding to the substrate and may be inserted into an internal space of the base plate. A coating layer made of alumina (Al2O3) may be formed on an outer surface of the base plate, an adhesive layer may be formed between the puck and the base plate to adhere the puck and the base plate, and a ring-shaped sealing member surrounding an outside of the adhesive layer may be provided between the puck and the base plate.

According to the present disclosure, by forming a temperature maintenance layer made of a phase change material on a base plate, abrupt temperature changes in a substrate can be prevented and a constant temperature can be maintained.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 schematically shows the structure of a plasma processing apparatus according to the present disclosure;

FIG. 2 shows an example of an electrostatic chuck including a temperature maintenance layer having a disk shape;

FIG. 3 shows an example of an electrostatic chuck including a temperature maintenance layer having a ring shape;

FIG. 4 shows an example of an electrostatic chuck including temperature maintenance layers spaced apart from each other;

FIG. 5 shows an example of an electrostatic chuck including temperature maintenance layers in contact with each other;

FIG. 6 shows an example of an electrostatic chuck including a temperature maintenance layer installed in a groove on the upper surface of a base plate;

FIG. 7 shows an example of an electrostatic chuck including a temperature maintaining layer having a tube shape; and

FIG. 8 is a flowchart showing a plasma processing method according to the present disclosure.

### DETAILED DESCRIPTION

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein.

In order to clearly describe the present disclosure, parts irrelevant to the description are omitted, and the same reference numerals are assigned to the same or similar components throughout the specification.

In addition, in various embodiments, components having the same configuration will be described only in representative embodiments by using the same reference numerals, and in other embodiments, only configurations different from the representative embodiments will be described.

Throughout the specification, when a part is said to be “connected (or coupled)” to another part, this includes not only the case of being “directly connected (or coupled)” but also “indirectly connected (or coupled)” with another member in between. In addition, when a part “includes”, “has”, or “comprises” a certain part, this means that other components may be further included without excluding other components unless otherwise stated.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed in ideal or excessively formal meanings unless expressly defined in this application.

Hereinafter, an electrostatic chuck 20, a plasma processing method, and a plasma processing apparatus 1 according to the present disclosure will be described. The plasma processing apparatus 1 is equipment for performing plasma processing (e.g., dry etching processing) on a substrate W. When the substrate W is input into the plasma processing apparatus 1, high-frequency power is applied to upper and lower electrodes to generate an electromagnetic field, and processing gas supplied to the substrate W is converted into a plasma state by the electromagnetic field and reacts with a specific material of the substrate W. The substrate W that has been plasma processed for a predetermined period of time is discharged to the outside of the plasma processing apparatus 1, and a subsequent processing process continues.

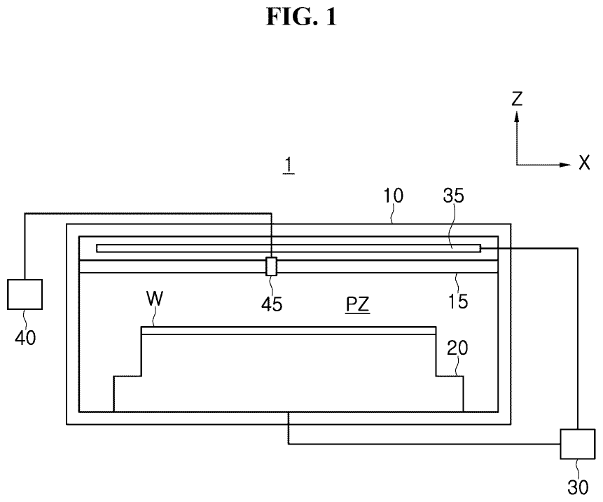

FIG. 1 schematically shows the structure of the plasma processing apparatus 1 according to the present disclosure. The plasma processing apparatus 1 includes: a chamber 10 forming a plasma processing space PZ for the substrate W; the electrostatic chuck 20 supporting the substrate W; an upper electrode 35 generating plasma in the plasma processing space PZ; a window 15 that separates the upper electrode 35 from the plasma processing space PZ; a power source 30 that supplies power to the upper electrode 35; a gas supply member 45 that supplies processing gas to the plasma processing space PZ; and a gas supply source 40 that supplies the processing gas to the gas supply member 45. In addition, although not specifically shown, the plasma processing apparatus 1 may be equipped with: an opening/closing door that opens or blocks the chamber 10 to the external space; and a baffle for discharging by-products and gases generated by plasma processing to the outside.

The chamber 10 provides the plasma processing space PZ for the substrate W, and components for plasma processing are installed inside the chamber 10. The window 15, the upper electrode 35, and the gas supply member 45 are located in the upper part of the chamber 10, and the electrostatic chuck 20 is located in the lower part of the chamber 10.

The window 15 separates the upper space where the upper electrode 35 is located from the plasma processing space PZ. The window 15 is provided to cover the upper part of the chamber 10 to seal the internal space of the chamber 10. The window 15 may be provided in the shape of a plate (e.g., a disk) and may be formed of an insulating material (e.g., alumina (Al2O3)).

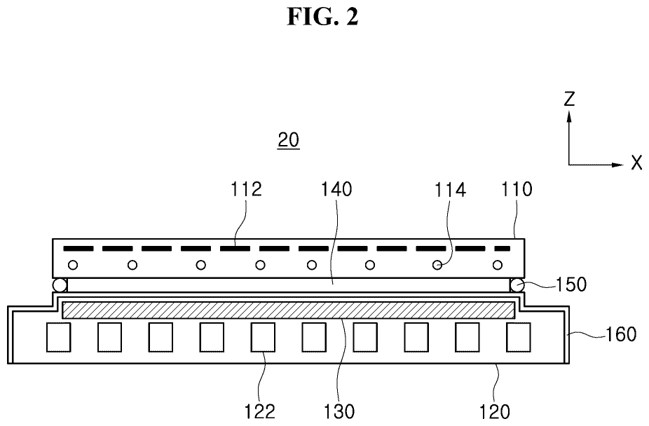

The electrostatic chuck 20 is provided at the bottom of the chamber 10 and supports the substrate W using electrostatic force. The detailed structure of the electrostatic chuck 20 according to the present disclosure will be described later with reference to FIGS. 2 to 7.

The power source 30 applies power to the upper electrode and a lower electrode provided inside the electrostatic chuck 20. The power source 30 may be provided to control the characteristics of plasma. The power source 30 may be provided to regulate ion bombardment energy, for example. In FIG. 1, although the power source 30 is shown as connected to both the upper electrode 35 and the electrostatic chuck 20, an upper power source connected to the upper electrode 35 and a lower power source connected to the electrostatic chuck 20 may be individually configured. In addition, the upper power source may include multiple power sources, and the lower power source may include multiple power sources. When a plurality of upper power sources is provided, a matching network electrically connected to the plurality of upper power sources may be provided in the plasma processing apparatus 1. The matching network may match frequency powers of different magnitudes input from the upper and lower power sources and apply the powers to the upper electrode 35 and the electrostatic chuck 20. Meanwhile, an impedance matching circuit (not shown) may be provided on a transmission line connecting the upper power source, the lower power source, the upper electrode 35, and the electrostatic chuck 20 for the purpose of impedance matching.

The upper electrode 35 generates plasma from gas remaining in the plasma processing space PZ. In this case, the plasma processing space PZ refers to the space located above the electrostatic chuck 20 in the internal space of the chamber 10. The upper electrode 35 may generate plasma according to an inductively coupled plasma method or a capacitively coupled plasma method. The upper electrode 35 may generate an electromagnetic field from power supplied from the power source 30. A matching circuit for impedance matching may be configured between the upper electrode 35 and the power source 30.

The gas supply source 40 supplies etching gas used to process the substrate W as a processing gas. The gas supply source 40 may provide a gas containing a fluorine element (e.g., a gas containing SF6 or CF4) as an etching gas to the gas supply member 45.

The gas supply member 45 may be installed to face the electrostatic chuck 20 in a vertical direction Z in the upper part of the chamber 10. The gas supply member 45 may be provided with a plurality of gas injection holes to inject gas into the interior of the chamber 10. The gas supply member 45 may be provided to have a larger diameter than the electrostatic chuck 20 in a horizontal direction X. The gas supply member 45 may be a showerhead including a plurality of gas injection holes. In addition, the gas supply member 45 may be a structure having one or more gas supply nozzles. Meanwhile, the gas supply member 45 may be manufactured using a silicon element, and may also be manufactured using a metal element.

Hereinafter, the electrostatic chuck 20 according to the present disclosure will be described with reference to FIGS. 2 to 7. The electrostatic chuck 20 is provided at the bottom of the chamber 10 and supports the substrate W using electrostatic force. An electrode 112 may be provided inside the electrostatic chuck 20 to bring the substrate W into close contact with the electrostatic chuck 20 using electrostatic force. The electrostatic chuck 20 may function as a lower electrode for generating plasma.

Referring to FIG. 2, the electrostatic chuck 20 includes: a puck 110 on which the substrate W for plasma processing is seated and having a heater 114; and a base plate 120 located below the puck 110 and having a cooling passage 122 through which fluid for cooling flows.

The puck 110 is a structure that supports the substrate W from the bottom, and is provided with the electrode 112 and the heater 114 therein. The puck 110 may be made of a ceramic material (e.g., quartz).

The base plate 120 is provided in a disk shape made of metal (e.g., Al) material. The base plate 120 may be composed of a lower region with a predetermined diameter and an upper region with a smaller diameter than the lower region. The cooling passage 122 may be provided in the lower region of the base plate 120. The upper region of base plate 120 may be coupled to puck 110. That is, the base plate 120 may have a shape in which the lower region protrudes. Although not shown, an edge ring (not shown) may be provided on the protruding portion of the base plate 120 to control plasma at the edge of the substrate W.

According to the present disclosure, a temperature maintenance layer 130 composed of a phase change material (PCM) is provided inside the base plate 120. The phase change material is a substance used to absorb or emit thermal energy. The phase change material is a substance that transforms between solid, liquid, or gas states. The phase change material may be used to control the temperature of the electrostatic chuck 20. The phase change material may absorb or release heat by melting or solidifying at a predetermined operating temperature. As the phase change material, paraffin, n-Dodecane (Cl2H26), polyethylene, magnesium chloride hydrate (MgCl2·6H2O), etc. may be used.

The temperature maintenance layer 130 may prevent abrupt temperature changes in the electrostatic chuck 20 and the substrate W by absorbing or emitting heat during a phase change process that occurs at a predetermined temperature.

Referring to FIG. 2, the temperature maintenance layer 130 may have a disk shape corresponding to the substrate W. That is, the temperature maintenance layer 130 having a disk shape may be provided inside the base plate 120. The temperature may be maintained constant in the entire area of the electrostatic chuck 20 and the substrate W by the temperature maintenance layer 130 having a disk shape.

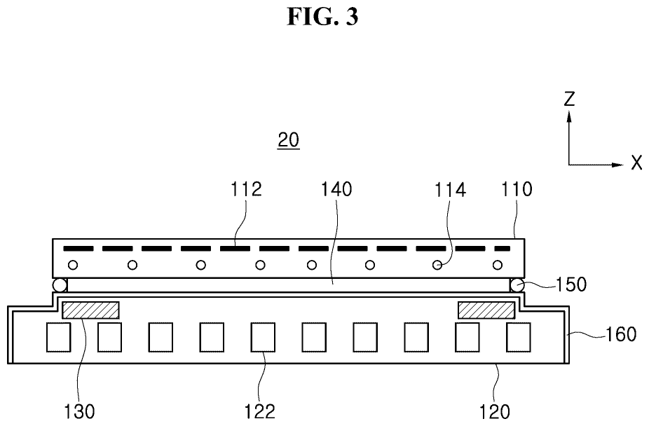

Referring to FIG. 3, the temperature maintenance layer 130 may have a ring shape corresponding to the edge area of the substrate W. In FIG. 3, the temperature maintenance layer 130 having a ring shape may be provided inside the base plate 120. The temperature of the edge area of the substrate W may be maintained constant by the temperature maintenance layer 130 having a ring shape. In general, during a plasma processing process, there is a large change in temperature at the edge area of the substrate W. Accordingly, as shown in FIG. 3, by disposing the ring-shaped temperature maintenance layer 130 inside the base plate 120, abrupt temperature changes occurring in the edge area of the substrate W may be prevented.

According to an embodiment of the present disclosure, the phase change material of the temperature maintenance layer 130 may be determined based on the processing temperature of the substrate W. A phase change temperature of the phase change material is determined according to the characteristics of the material. The phase change material used for the temperature maintenance layer 130 is determined by the processing temperature for the substrate W. For example, if the processing temperature of the substrate W is 120° C., a phase change material with a phase change temperature close to 120° C. may be used, and if the processing temperature of the substrate W is −10° C., a phase change material with a phase change temperature close to −10° C. may be used.

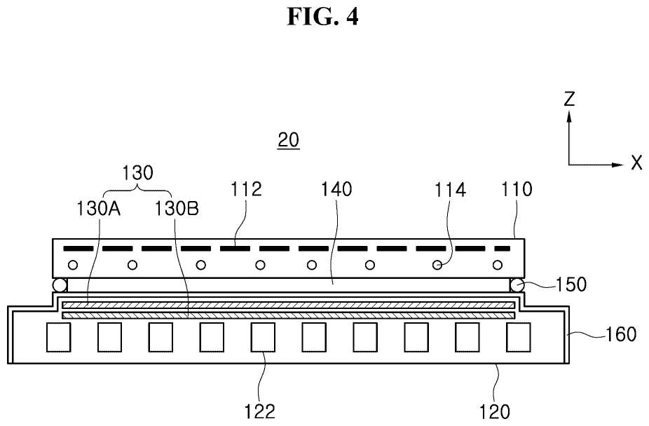

According to an embodiment of the present disclosure, the temperature maintenance layer 130 may include: a first temperature maintenance layer 130A composed of a first phase change material; and a second temperature maintenance layer 130B stacked in the vertical direction Z on the first temperature maintenance layer 130A and made of a second phase change material different from the first phase change material. As shown in FIG. 4, the temperature maintenance layer 130 may be formed by the first temperature maintenance layer 130A and the second temperature maintenance layer 130B stacked in the vertical direction Z. The first temperature maintenance layer 130A and the second temperature maintenance layer 130B are made of different phase change materials. For example, the phase change material of the first temperature maintenance layer 130A may be composed of a material that changes phase at about 120° C., while the phase change material of the second temperature maintenance layer 130B may be composed of a material that changes phase at about −10° C. The phase change material of the first temperature maintenance layer 130A may be polyethylene, which has a phase change temperature of 120 to 140° C., or magnesium chloride hydrate (MgCl2·6H2O), which has a phase change temperature of about 118° C. The phase change material of the second temperature maintenance layer 130B may be n-dodecane (Cl2H26), which has a phase change temperature of approximately −10° C.

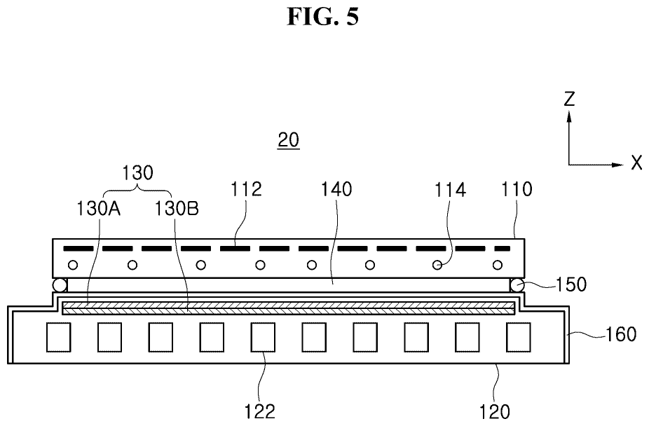

As shown in FIG. 4, the first temperature maintenance layer 130A and the second temperature maintenance layer 130B may be stacked while being spaced apart from each other. Alternatively, as shown in FIG. 5, the first temperature maintenance layer 130A and the second temperature maintenance layer 130B may be stacked in contact with each other. The materials and positions of the first temperature maintenance layer 130A and the second temperature maintenance layer 130B may be determined according to material properties and temperature transfer characteristics.

According to an embodiment of the present disclosure, the temperature maintenance layer 130 may be inserted into the internal space of the base plate 120. Referring to FIG. 2, an empty space of a certain area is formed inside the base plate 120, and the temperature maintenance layer 130 may be inserted into the empty space.

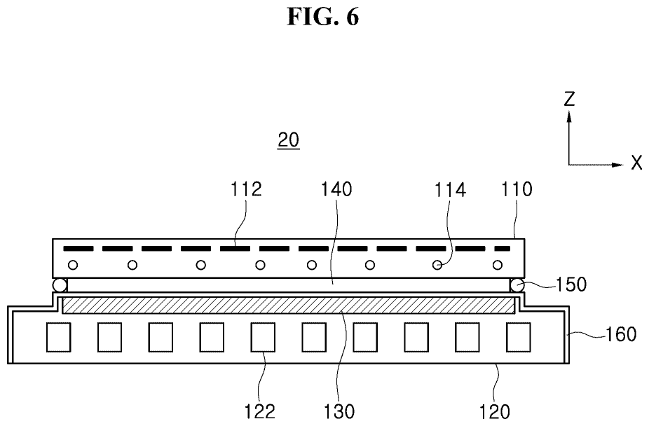

Meanwhile, as shown in FIG. 6, the temperature maintenance layer 130 may be coupled to a groove formed on the upper surface of the base plate 120. Referring to FIG. 6, a circular groove is formed on the upper surface of the base plate 120, and the temperature maintenance layer 130 may be inserted into the groove. In this case, an adhesive layer 140 may be formed over the temperature maintenance layer 130.

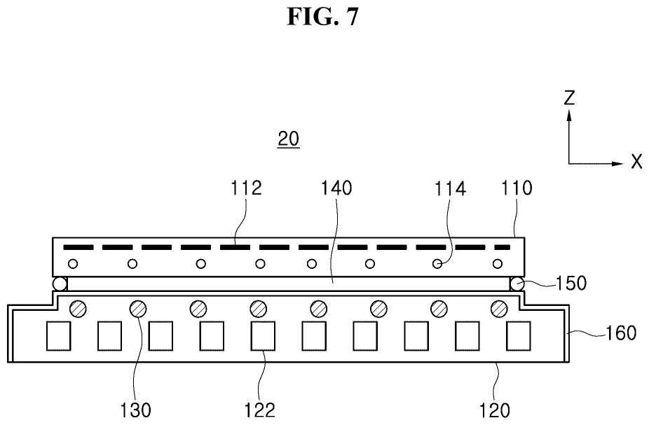

Meanwhile, as shown in FIG. 7, the temperature maintenance layer 130 may be composed of a tube inserted into a circular conduit formed in the base plate 120. Referring to FIG. 7, the circular conduit is formed in the base plate 120, and by inserting a phase change material in the form of a tube into the pipe, the temperature maintenance layer 130 may be formed.

As shown in FIGS. 2 to 7, a coating layer 160 made of alumina (Al2O3) may be formed on the outer surface of the base plate 120. The coating layer 160 prevents the base plate 120 made of metal (e.g., Al) from being exposed to the external environment, especially plasma.

In addition, the adhesive layer 140 is formed between the puck 110 and the base plate 120 to adhere the puck 110 and the base plate 120. The base plate 120 and the puck 110 may be adhered to each other by the adhesive layer 140 made of an adhesive material. A ring-shaped sealing member 150 surrounding the outside of the adhesive layer 140 may be provided between the puck 110 and the base plate 120. The sealing member 150 seals the adhesive layer 140, thereby preventing the adhesive layer 140 from being exposed to the external environment, especially plasma.

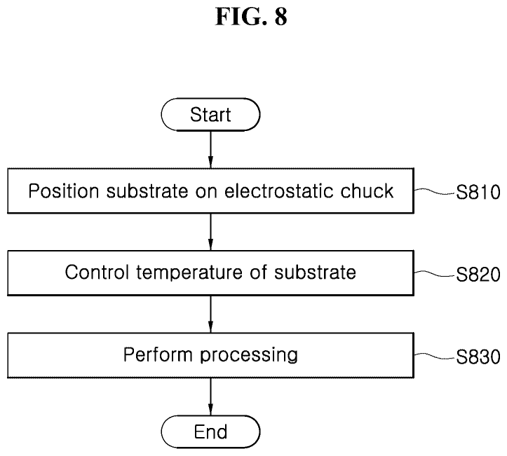

FIG. 8 is a flowchart showing a plasma processing method according to the present disclosure. The plasma processing method according to the present disclosure may be carried out by the plasma processing apparatus 1 shown in FIG. 1. The plasma processing method according to the present disclosure includes: positioning (S810) a substrate W on an electrostatic chuck 20 including a puck 110 with a heater 114 and a base plate 120 located below the puck 110 and having a cooling passage 122 formed therein; controlling (S820) the temperature of the substrate W by adjusting the output of the heater 114 and supplying coolant to the cooling passage 122; and performing (S830) processing on the substrate using plasma.

In step S810, the substrate W is introduced into a chamber 10 by a wafer transfer robot and is placed on the top of the electrostatic chuck 20. The substrate W may be brought into close contact with the electrostatic chuck 20 by the electrostatic force of an electrode 112.

In step S820, the temperature of the substrate W is controlled by the heater 114 and the coolant. The output of the heater 114 and the supply flow rate of the coolant may be determined depending on the target temperature. Meanwhile, a temperature maintenance layer 130 made of a phase change material is provided inside the base plate 120. The phase change material may delay the temperature change of the puck 110 and the base plate 120 by absorbing or releasing heat during a phase change process. That is, the phase change material of the temperature maintenance layer 130 prevents abrupt temperature changes in the electrostatic chuck 20 and the substrate W. The phase change material of the temperature maintenance layer 130 may be determined based on the processing temperature of the substrate W.

In step S830, power is applied to an upper electrode 35 and the electrostatic chuck 20, and plasma processing on the substrate W is performed by supplying the processing gas to a plasma processing space PZ by a gas supply member 45. At this time, the temperature of the substrate W is controlled by the heater 114 and the coolant, and the temperature of the substrate W may be maintained constant by the temperature maintenance layer 130.

The present embodiments and the drawings accompanying this specification only clearly show some of the technical ideas included in the present disclosure, and it will be apparent that all modifications and specific embodiments that may be easily inferred by those skilled in the art within the scope of the technical idea included in the specification and drawings of the present disclosure are included in the scope of the present disclosure.

Therefore, the spirit of the present disclosure should not be limited to the described embodiments, and it will be said that not only the claims to be described later but also all things that are equivalent to the claims or have equivalent modifications belong to the scope of the present disclosure.

What is claimed is:

1. An electrostatic chuck comprising:
a puck on which a substrate for plasma processing is seated and having a heater;
a base plate located below the puck and having a cooling passage through which fluid for cooling flows; and
a temperature maintenance layer composed of a phase change material and provided inside the base plate.

2. The electrostatic chuck of claim 1, wherein the temperature maintenance layer has a disk shape corresponding to the substrate.

3. The electrostatic chuck of claim 1, wherein the temperature maintenance layer has a ring shape corresponding to an edge area of the substrate.

4. The electrostatic chuck of claim 1, wherein the phase change material of the temperature maintenance layer is determined based on a processing temperature of the substrate.

5. The electrostatic chuck of claim 1, wherein the temperature maintenance layer comprises:
a first temperature maintenance layer composed of a first phase change material; and
a second temperature maintenance layer stacked in a vertical direction on the first temperature maintenance layer and composed of a second phase change material different from the first phase change material.

6. The electrostatic chuck of claim 5, wherein the first temperature maintenance layer and the second temperature maintenance layer are stacked in contact with each other.

7. The electrostatic chuck of claim 5, wherein the first temperature maintenance layer and the second temperature maintenance layer are stacked while being spaced apart from each other.

8. The electrostatic chuck of claim 1, wherein the temperature maintenance layer is inserted into an internal space of the base plate.

9. The electrostatic chuck of claim 1, wherein the temperature maintenance layer is composed of a tube inserted into a circular conduit provided in the base plate.

10. The electrostatic chuck of claim 1, wherein the temperature maintenance layer is coupled to a groove formed on an upper surface of the base plate.

11. The electrostatic chuck of claim 1, wherein a coating layer made of alumina (Al2O3) is formed on an outer surface of the base plate.

12. The electrostatic chuck of claim 1, wherein an adhesive layer is formed between the puck and the base plate to adhere the puck and the base plate.

13. The electrostatic chuck of claim 12, wherein a ring-shaped sealing member surrounding an outside of the adhesive layer is provided between the puck and the base plate.

14. A plasma processing method, comprising:
positioning a substrate on an electrostatic chuck including a puck with a heater and a base plate located below the puck and having a cooling passage formed therein;
controlling a temperature of the substrate by adjusting an output of the heater and supplying coolant to the cooling passage; and
performing processing on the substrate using plasma,
wherein a temperature maintenance layer composed of a phase change material is provided inside the base plate.

15. The plasma processing method of claim 14, wherein the phase change material delays a temperature change of the puck and the base plate by absorbing or releasing heat during a phase change process.

16. The plasma processing method of claim 14, wherein the phase change material of the temperature maintenance layer is determined based on a processing temperature of the substrate.

17. A plasma processing apparatus comprising:
a chamber configured to form a plasma processing space for a substrate;
an electrostatic chuck configured to support the substrate;
an upper electrode configured to generate plasma in the plasma processing space;
a window configured to separate the upper electrode from the plasma processing space;
a power source configured to supply power to the upper electrode;
a gas supply member configured to supply a processing gas to the plasma processing space; and
a gas supply source configured to supply the processing gas to the gas supply member,
wherein the electrostatic chuck comprises:
a puck on which the substrate for plasma processing is seated and having a heater;
a base plate located below the puck and having a cooling passage through which fluid for cooling flows;
a temperature maintenance layer composed of a phase change material and provided inside the base plate, wherein the temperature maintenance layer has a disk shape corresponding to the substrate and is inserted into an internal space of the base plate;
a coating layer made of alumina (Al2O3) formed on an outer surface of the base plate;
an adhesive layer formed between the puck and the base plate to attach the puck to the base plate, and
a ring-shaped sealing member surrounding an outside of the adhesive layer and provided between the puck and the base plate.

18. The plasma processing apparatus of claim 17, wherein the phase change material delays a temperature change of the puck and the base plate by absorbing or releasing heat during a phase change process.

19. The plasma processing apparatus of claim 17, wherein the temperature maintenance layer comprises:
a first temperature maintenance layer composed of a first phase change material; and
a second temperature maintenance layer stacked in a vertical direction on the first temperature maintenance layer and composed of a second phase change material different from the first phase change material.

20. The plasma processing apparatus of claim 17, wherein the phase change material of the temperature maintenance layer is determined based on a processing temperature of the substrate.
